(19) United States
(12) Patent Application Publication
(10) Pub. No.: US 2007/0262801 A1
(43) Pub. Date: Nov. 15, 2007

(54) Pulse width modulation circuit and method therefor

(75) Inventors: Mathieu Renaud, Chomedey (CA); Hugues Langlois, St-Roch de I'Achigan (CA)

Correspondence Address: BCF LLP, 25th Floor, 1100 Rene-Levesque Boulevard West, Montreal, QC, H3B 5C9, CA

(73) Assignee: TECHNOLOGIES LTRIM INC.

(21) Appl. No.: 11/430,928

(22) Filed: May 10, 2006

(51) Int. Cl. H03K 3/017

(52) U.S. Cl. 327/172

(57) ABSTRACT

A pulse width modulation circuit comprising an oscillator, a ramp generator and a comparator where the offset level of the ramp generated by the ramp generator varies and where the value of the voltage supplied to the comparator is constant is described herein. By varying the offset level of the ramp, it is possible to modulate the width of the pulse of the output signal of the circuit.

### FIELD OF THE INVENTION

The present invention generally relates to pulse width modulation circuits and methods.

### BACKGROUND OF THE INVENTION

Pulse width modulation circuits (PWM circuits) are well known in the art. FIG. 1, which is labelled “Prior Art” schematically illustrates a conventional pulse width modulation circuit 10 including an oscillator 12, a ramp generator 14 and a comparator 16. The oscillator generates a pulse train 18 that is supplied to the input of the ramp generator 14. The ramp generator 14 uses the basis frequency of the pulse train 18 to generate a ramp 20 for example by charging a capacitor (not shown) part of the ramp generator 14. The ramp 20 is supplied to a comparator that compares it to a control voltage Vctrl. If the voltage level of the ramp 20 is higher that Vctrl, the output OUT of the comparator 16 is in a low state (ground) and if the voltage level of the ramp 20 is lower that Vctrl, the output OUT of the comparator 16 is in a high state (Vdd).

Accordingly, by varying the value of Vctrl, it is possible to change the duration of the high state, therefor of the width of the pulse. FIGS. 2A, 2B and 2C, which are also labelled “Prior Art”, illustrate the effect of the variation of the value of Vctrl on the pulse width of the output OUT. The pulse width is therefore modulated by the value of Vctrl. It can be seen from these figures that the ramp 20 has no offset value, starting from the ground and ramping to Vdd and that the Vctrl is variable.

A drawback of this conventional pulse width modulation circuit and its associated method is the number of transistors that are required to operate it. All together, an optimized and performing design of the three modules (oscillator, ramp generator and comparator) easily comes up to more than 100 transistors and occupy a significant silicon area. Also, the comparator needed in the PWM generator of FIG. 1 must be able to accurately compare its two inputs over the all voltage range. of the ramp generator output. This kind of wide range comparators conventionally show an important tradeoff between speed and current consumption.

It would therefore be interesting to provide a pulse width modulation circuit using less transistors and therefore drawing less power. Also, an approach that would run faster and draw less current would also be interesting.

### OBJECTS OF THE INVENTION

An object of the present invention is therefore to provide a pulse width modulation circuit and method therefor.

### SUMMARY OF THE INVENTION

More specifically, in accordance with the present invention, there is provided a pulse width modulation circuit comprising:

an oscillator generating a pulse train;

a ramp generator receiving the pulse train; the ramp generator including a control input and a ramp output; the ramp generator being so configured as to generate a ramp signal having an offset level which is a function of control signal present at the control input; and

a comparator comparing the ramp signal to a fixed voltage value to yield an output pulse signal;

whereby, the width of the output pulse signal is modulated by the variation of the control signal presented to the control input.

According to another aspect of the present invention, there is provided a modulation circuit having an input to receive a control signal and an output that generates a pulse signal having a pulse width that is a function of the control signal; the modulation circuit comprising:

an oscillator generating a pulse train;

a ramp generator receiving the pulse train and the control signal; the ramp generator being so configured as to generate a ramp signal having an offset level which is a function of the control signal; and

a comparator comparing the ramp signal to a fixed voltage value to yield the pulse signal at the output of the modulation circuit.

According to another aspect of the present invention, there is provided a method to generate a pulse signal having a pulse width that is modulated by a control signal; the method comprising:

generating a periodic ramp signal having an offset level which is a function of the control signal; and

comparing the periodic ramp signal to a fixed voltage value to yield a pulse width modulated output pulse signal.

Other objects, advantages and features of the present invention will become more apparent upon reading of the following non-restrictive description of illustrative embodiments thereof, given by way of example only with reference to the accompanying drawings.

### BRIEF DESCRIPTION OF THE DRAWINGS

In the appended drawings:

FIG. 1, which is labelled “Prior Art” is a schematic representation of a conventional PWM circuit;

FIGS. 2A, 2B and 2C, which are labelled “Prior Art”, are diagrams of the different signals of the PWM circuit of FIG. 1 for different duty cycles;

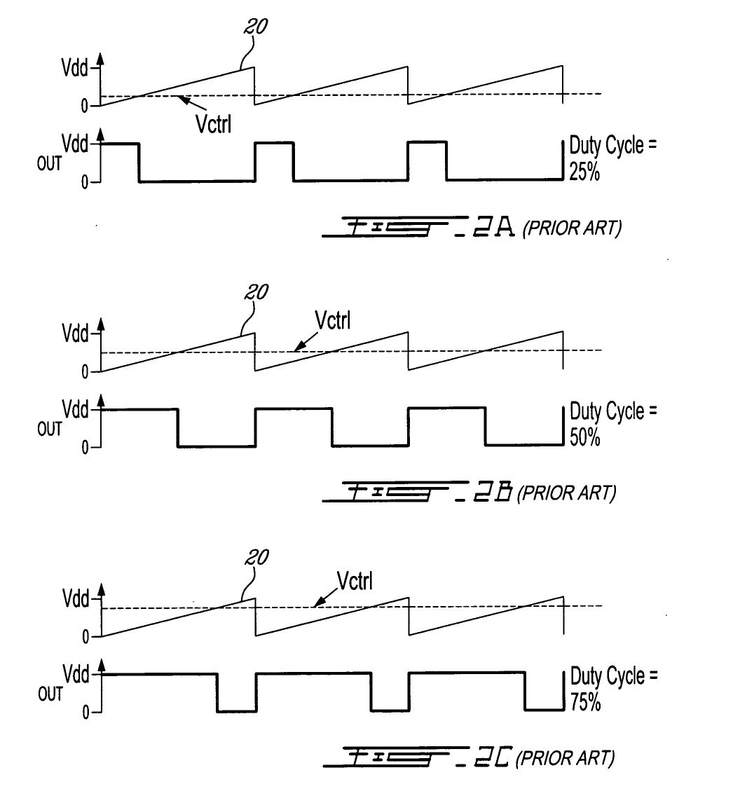

FIG. 3 is a schematic representation of a PWM circuit according to an illustrative embodiment of the present invention;

FIGS. 4A, 4B and 4C are diagrams of the different signals of the PWM circuit of FIG. 2 for different duty cycles;

FIG. 5 is a PWM circuit according to an illustrative embodiment of the present invention; and

FIG. 6 is a diagram illustrating nodes N3 and N5 of FIG. 5.

### DETAILED DESCRIPTION

Generally stated, an illustrative embodiment of the present invention proposes a PWM circuit comprising an oscillator, a ramp generator and a comparator where the offset level of the ramp generated by the ramp generator varies and where the value of the voltage supplied to the comparator is constant. Therefore, by varying the offset level of the ramp, it is possible to modulate the width of the pulse of the output signal of the circuit.

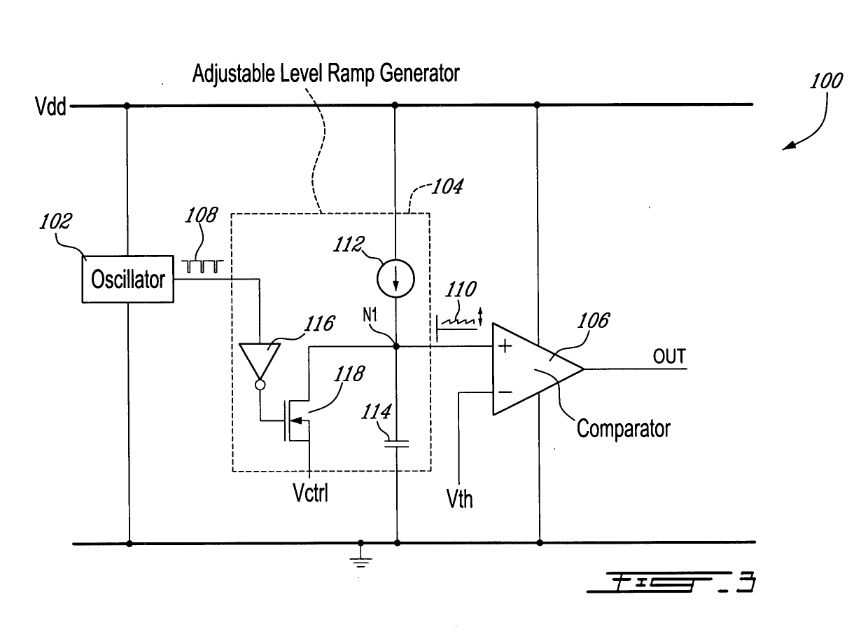

Turning now to FIG. 3 of the appended drawings, a PWM circuit 100 according to an illustrative embodiment of the present invention will be described. It is to be noted that the PWM circuit 100 is schematically illustrated in FIG. 3.

The PWM circuit 100 includes an oscillator 102, a adjustable level ramp generator 104 and a fixed value comparator 106.

The oscillator 102 generates a pulse train 108 that is supplied to the adjustable level ramp generator 104 that generates a ramp 110 having a constant amplitude but having an offset level that is dictated by a control signal (Vctrl) that is presented at a control input of the circuit. More specifically, the current source 112 charges a capacitor 114 that is connected to ground that gives the desired ramp slope.

The pulse train 108 supplies an inverter 116 connected to the gate of a switch 118. The source of the switch 118 is connected to Vctrl and the drain of the switch 118 is connected to the node N1. Accordingly, as long as the pulse train 108 is in its high state, the signal supplied to the gate is zero and the switch 118 is open.

When the pulse train 108 switches from its high state to its low state, i.e. from Vdd to the ground, the inverted 116 switches from ground to Vdd and thus closes the switch 118, thereby interconnecting the node N1 to the Vctrl. Accordingly, the voltage value at node N1 will decrease rapidly until it reaches Vcrtl where it will stabilize.

It is to be noted that the pulse train 108 remains in its low state long enough to discharge the capacitor 114 to the Vctrl level.

The ramp signal 110 is supplied to the comparator 106 that compares it to a fixed threshold value Vth to determine the value of the output OUT of the comparator 106.

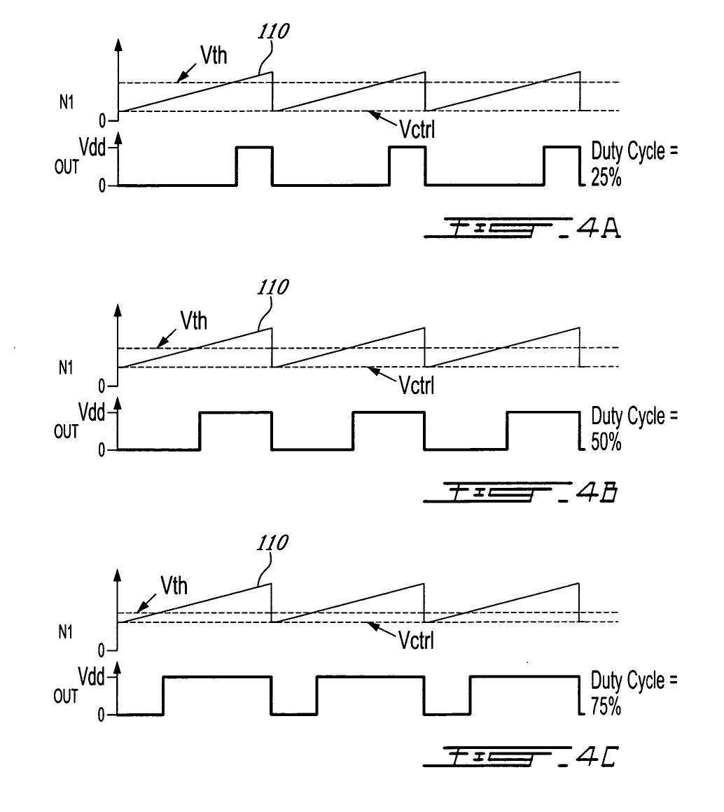

FIG. 4A illustrates the ramp signal at node N1 and the output OUT of the comparator 106 for a duty cycle of 25%, i.e. when the OUT signal is at the high state 25% of the time. As can be seen from the top portion of this figure, it means that the value of the ramp 110 is greater that Vth 25% of the time.

Similarly, FIG. 4B illustrates the ramp signal at node N1 and the output OUT of the comparator 106 for a duty cycle of 50%. As can be seen from the top portion of this figure, it means that the value of the ramp 110 is greater that Vth 50% of the time. It is to be noted that since the value of Vth is constant, to achieve the 50% duty cycle, the value of Vctrl has been increased as compared to FIG. 4A, thereby increasing the offset level of the ramp 110.

Finally, FIG. 4C illustrates the ramp signal at node N1 and the output OUT of the comparator 106 for a duty cycle of 75%. As can be seen from the top portion of this figure, it means that the value of the ramp 110 is greater that Vth 75% of the time. Again, since the value of Vth is constant, to achieve the 75% duty cycle, the value of Vctrl has been increased as compared to FIG. 4B, thereby increasing the offset level of the ramp 110.

As will easily be understood by one skilled in the art, since the comparator 106 compares the ramp signal 110 to a fixed voltage Vth, the comparator 106 may be much simpler than the wide range comparator of the prior art approach that would conventionally compare a ramp voltage to a variable control voltage.

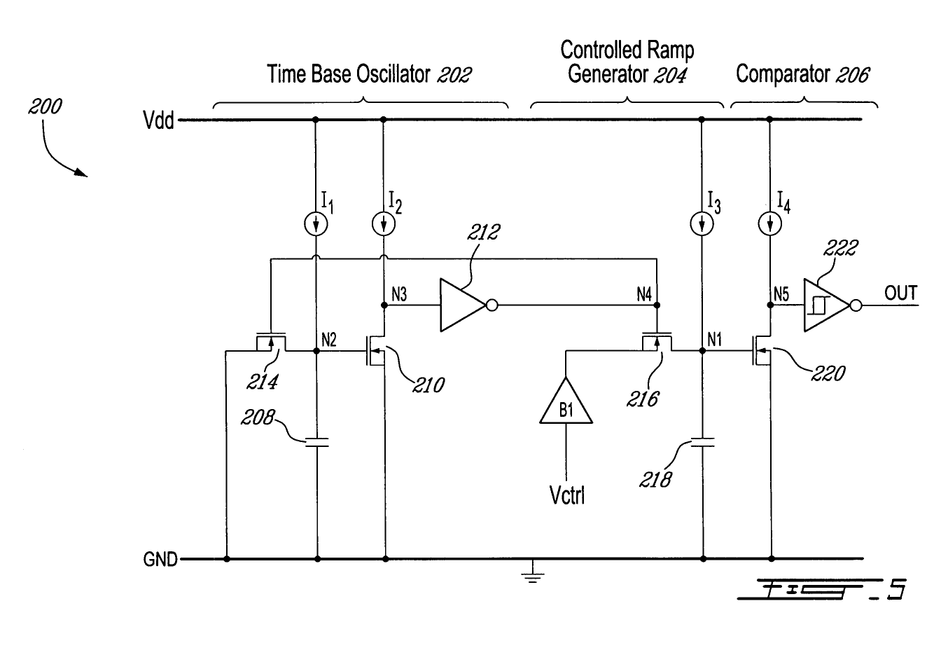

Turning now to FIG. 5 of the appended drawings, a PWM circuit 200 according to a second illustrative embodiment of the present invention will be described. The PWM circuit 200 includes three main sections, a time base oscillator 202, a controlled ramp generator 204 and a comparator 206.

Time Base Oscillator 202

Generally stated, this portion of the circuit generates a time base signal that determines the basic frequency of the output signal (OUT) of the PWM generator 200. The time based oscillator 202 may be viewed as a ramp based oscillator since it mainly uses the charging of a capacitor as a time counter, as will be described hereinbelow.

The capacitor 208 is charged by the current source I₁ until the voltage on node N2 reaches the threshold voltage (Vth) of the transistor 210.

At this point, the transistor 210 is switched on and the node N3 switches from supply voltage Vdd to ground. This switching of the node N3 makes the output N4 of the inverter 212 switch from ground to Vdd. The voltage on node N4 then switches on the transistor 214, threreby connecting the node N2 to the ground, discharging the capacitor 208 in the process and making the nodes N3 and N4 to switch again since the voltage at node N2 becomes smaller than Vth of the transistor 210, switching off the transistor 210.

It is to be noted that a sufficient delay as to be implemented in inverter 212 so that the capacitor 208 can be completely discharged before node N4 switches to ground and stop the discharge by switching off the transistor 214.

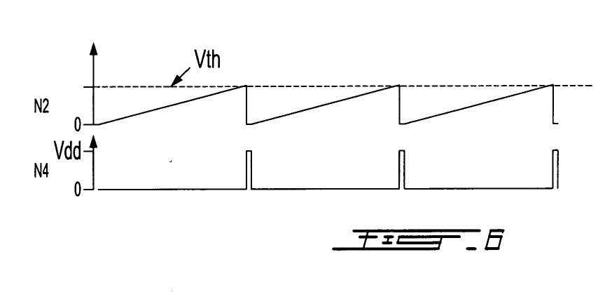

On FIG. 6, the voltages on nodes N2 and N4 are shown. Each pulse of the pulse train on node N4 sets the end of the charge cycle of capacitor 208 and the width of this pulse represents the delay implemented in the inverter 212. The time for a complete cycle is determined by the value of the current source I₁ and the value of the capacitor 208.

As will easily be understood by one skilled in the art, the values of the capacitor 208, which is typically integrated on a chip may vary from about 100 femtoFarads to about 100 picoFarads. Depending on the operation frequency, the current source I₁ may be rated to supply from about 100 nanoamperes to about 20 milliamperes.

As will also be easily understood by one skilled in the art, the current source 12 is present mainly to limit the current going through the transistor 210 when it is in its conducting state, i.e. when it is switched on.

Controlled Ramp Generator 204 and Comparator 206

In the PWM generator circuit 200, the control signal Vctrl is not compared to a ramp signal. Instead, as generally described hereinabove, the control voltage signal Vctrl is used to define the offset level of the periodic ramp signal on node N1 so that the time the voltage on node N1 takes to reach the threshold voltage of transistor 220 is related to the value of the control signal Vctrl.

As will be understood by one skilled in the art, the comparator 206 is mainly a transistor since the value to be compared to is the threshold value of the transistor.

More specifically, when the pulse on node N4, described hereinabove, sets the beginning of a new cycle, the voltage on node N1 is set to Vctrl by the switching on of the transistor 216. The capacitor 218 therefore starts to be charged via the current source 13, but starts at the offset forced by Vctrl. When the voltage on node N1 reaches the threshold voltage of transistor 220, the voltage on node N5 switches from Vdd to ground and the output signal (OUT) of the Schmitt inverter 222 switches from the ground to the supply voltage Vdd. Since the voltage increase node N1 is relatively slow, the Schmitt inverter 222 ensures that the output signal (OUT) of the circuit 200 remains stable even when the voltage at node N1 is close to the threshold of the transistor 220.

During the rest of the cycle, the capacitor 218 continues to charge without changing the state of the output signal (OUT). When the voltage on the node N4 switches to Vdd again, the capacitors 208 and 218 are discharged, the node N2 is brought to ground via the conducting state of the transistor 214, the node N1 is brought to Vctrl through the buffer B1 via the conducting state of the transistor 216, and the cycle starts again.

It is to be noted that the buffer B1 is mainly used to ensure that the charge from the capacitor 218 may be drawn quickly when the transistor 216 conducts so as to properly discharge the capacitor 218 to the level of Vctrl.

One skilled in the art will understand that the graphs of FIGS. 4A-4C apply to the PWM circuit 200 as described hereinabove.

As will easily be understood by one skilled in the art, the values of the capacitor 218, which is typically integrated on a chip may vary from about 100 femtoFarads to about 100 picoFarads. Depending on the operation frequency, the current source 13 may be rated to supply from about 100 nanoamperes to about 20 milliamperes.

As will also be easily understood by one skilled in the art, the current source 14 is present mainly to limit the current going through the transistor 220 when it is in its conducting state, i.e. when it is switched on.

Furthermore, it will be appreciated that to ensure proper implementation of the circuit 200 some of its elements should be properly matched. For example, capacitors 208 and 218; current sources I₁ and I₃ and current sources I₂ and I₄, respectively, should have similar values. This will result in similar time bases for both the time base oscillator 202 and of the controlled ramp generator 204.

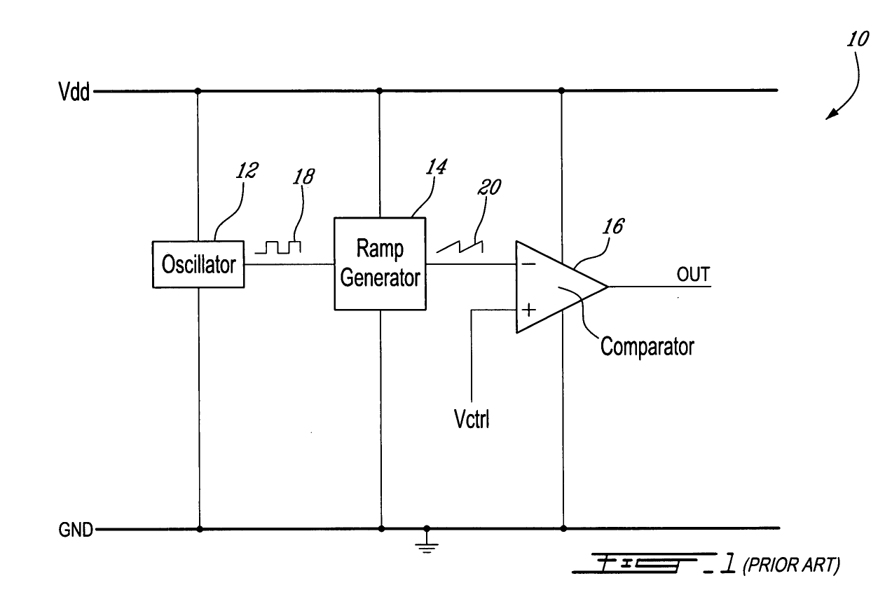

One skilled in the art will also understand that the total number of transistor used to implement the PWM circuit 200 can be as low as 15. Accordingly, the PWM circuit 200 uses less power than conventional PWM circuits such as circuit 10 illustrated in FIG. 1 and has a significantly smaller footprint.

Furthermore, the comparator 206 being mainly embodied by a simple transistor, it is posible to increase the operation frequency of the circuit 200 without consuming to much current.

It is to be understood that the invention is not limited in its application to the details of construction and parts illustrated in the accompanying drawings and described hereinabove. The invention is capable of other embodiments and of being practiced in various ways. It is also to be understood that the phraseology or terminology used herein is for the purpose of description and not limitation. Hence, although the present invention has been described hereinabove by way of illustrative embodiments thereof, it can be modified, without departing from the spirit, scope and nature of the subject invention as defined in the appended claims.

What is claimed is:

1. A pulse width modulation circuit comprising:
an oscillator generating a pulse train;
a ramp generator receiving the pulse train; the ramp generator including a control input and a ramp output; the ramp generator being so configured as to generate a ramp signal having an offset level which is a function of control signal present at the control input; and
a comparator comparing the ramp signal to a fixed voltage value to yield an output pulse signal; whereby, the width of the output pulse signal is modulated by the variation of the control signal presented to the control input.

2. The pulse width modulation circuit of claim 1, wherein the oscillator is a ramp based oscillator.

3. The pulse width modulation circuit of claim 2, wherein the ramp based oscillator includes a capacitor and a current source charging the capacitor.

4. The pulse width modulation circuit of claim 3, wherein the ramp based oscillator further includes a switch so controlled by the voltage of the capacitor as to force the capacitor to be discharged when a threshold voltage is reached by the capacitor.

5. The pulse width modulation circuit of claim 4, wherein the switch is a transistor.

6. The pulse width modulation circuit of claim 4, wherein the ramp based oscillator further includes a pulse generating switch so controlled as to be switched on when the threshold voltage is reached by the capacitor so as to generate the pulse train.

7. The pulse width modulation circuit of claim 6, wherein the pulse generating switch is a transistor.

8. The pulse width modulation circuit of claim 1, wherein the ramp generator includes a capacitor and a current source charging the capacitor.

9. The pulse width modulation circuit of claim 8, wherein the ramp generator further includes a switch so controlled by the pulse train from the oscillator as to periodically force the capacitor to be discharged to the voltage level of the control signal.

10. The pulse width modulation circuit of claim 9, wherein the switch is a transistor.

11. The pulse width modulation circuit of claim 9, wherein the ramp generator includes a buffer so configured as to ensure that the capacitor is adequately discharged to the voltage level of the control signal when so forced by the switch.

12. The pulse width modulation circuit of claim 1, wherein the comparator includes a switch so connected to the ramp generator as to be switched on when the voltage level reached by the ramp signal is higher than a threshold voltage of the switch and to remain in the switch on state while the voltage level of the ramp signal is higher than the threshold voltage.

13. The pulse width modulation circuit of claim 12, wherein the switch is a transistor.

14. The pulse width modulation circuit of claim 12, wherein the comparator further includes a Schmitt inverter so connected to the switch as to ensure that the output pulse signal remains stable.

15. The pulse width modulation circuit of claim 1, wherein:
the oscillator includes a first capacitor; a first current source charging the first capacitor; a first capacitor discharging switch so controlled by the voltage level of the first capacitor as to force the first capacitor to be discharged when a threshold voltage is reached by the first capacitor; a pulse generating switch so controlled as to be switched on when the threshold voltage is reached by the first capacitor so as to generate the pulse train; and
the ramp generator includes a second capacitor; a second current source charging the second capacitor; a second capacitor discharging switch so controlled by the pulse train as to periodically force the second capacitor to be discharged to the voltage level of the control signal.

16. The pulse width modulation circuit of claim 15, wherein said first and second capacitors have approximately the same value.

17. The pulse width modulation circuit of claim 15, wherein said first and second current sources have approximately the same value.

18. A modulation circuit having an input to receive a control signal and an output that generates a pulse signal having a pulse width that is a function of the control signal; the modulation circuit comprising:
an oscillator generating a pulse train;
a ramp generator receiving the pulse train and the control signal; the ramp generator being so configured as to generate a ramp signal having an offset level which is a function of the control signal; and
a comparator comparing the ramp signal to a fixed voltage value to yield the pulse signal at the output of the modulation circuit.

19. The pulse width modulation circuit of claim 18, wherein the oscillator is a ramp based oscillator.

20. The pulse width modulation circuit of claim 19, wherein the ramp based oscillator includes a capacitor and a current source charging the capacitor.

21. The pulse width modulation circuit of claim 20, wherein the ramp based oscillator further includes a switch so controlled by the voltage of the capacitor as to force the capacitor to be discharged when a threshold voltage is reached by the capacitor.

22. The pulse width modulation circuit of claim 21, wherein the ramp based oscillator further includes a pulse generating switch so controlled as to be switched on when the threshold voltage is reached by the capacitor so as to generate the pulse train.

23. The pulse width modulation circuit of claim 18, wherein the ramp generator includes a capacitor and a current source charging the capacitor.

24. The pulse width modulation circuit of claim 23, wherein the ramp generator further includes a switch so controlled by the pulse train from the oscillator as to periodically force the capacitor to be discharged to the voltage level of the control signal.

25. The pulse width modulation circuit of claim 25, wherein the ramp generator includes a buffer so configured as to ensure that the capacitor is adequately discharged to the voltage level of the control signal when so forced by the switch.

26. The pulse width modulation circuit of claim 18, wherein the comparator includes a switch so connected to the ramp generator as to be switched on when the voltage level reached by the ramp signal is higher than a threshold voltage of the switch and to remain in the switch on state while the voltage level of the ramp signal is higher than the threshold voltage.

27. The pulse width modulation circuit of claim 26, wherein the comparator further includes a Schmitt inverter so connected to the switch as to ensure that the output pulse signal remains stable.

28. The pulse width modulation circuit of claim 18, wherein:
the oscillator includes a first capacitor; a first current source charging the first capacitor; a first capacitor discharging switch so controlled by the voltage level of the first capacitor as to force the first capacitor to be discharged when a threshold voltage is reached by the first capacitor; a pulse generating switch so controlled as to be switched on when the threshold voltage is reached by the first capacitor so as to generate the pulse train; and
the ramp generator includes a second capacitor; a second current source charging the second capacitor; a second capacitor discharging switch so controlled by the pulse train as to periodically force the second capacitor to be discharged to the voltage level of the control signal.

29. The pulse width modulation circuit of claim 28, wherein said first and second capacitors have approximately the same value.

30. The pulse width modulation circuit of claim 28, wherein said first and second current sources have approximately the same value.

31. A method to generate a pulse signal having a pulse width that is modulated by a control signal; the method comprising:
generating a periodic ramp signal having an offset level which is a function of the control signal; and
comparing the periodic ramp signal to a fixed voltage value to yield a pulse width modulated output pulse signal.

32. The pulse signal generation method of claim 31, wherein the periodic ramp signal generating includes charging a capacitor via a current source and periodically discharging the capacitor the offset level.

33. The pulse signal generation method of claim 32, wherein the periodically discharging is done via a switch controlled by a pulse train.

34. The pulse signal generation method of claim 31, wherein the periodic signal comparing includes supplying the periodic ramp to a transistor and comparing the ramp signal level to the threshold level of the transistor.
